(19) United States
(12) Patent Application Publication
(10) Pub. No.: US 2005/0182500 A1
(43) Pub. Date: Aug. 18, 2005

(54) Time delay definition

(75) Inventors: Vadim Shapiro, Clive, IA (US); Dmitriy Khots, West Des Moines, IA (US); Ilya Markevich, West Des Moines, IA (US)

Correspondence Address: ZARLEY LAW FIRM P.L.C., CAPITAL SQUARE, 400 LOCUST, SUITE 200, DES MOINES, IA, 50309-2350, US

(73) Assignee: Continuous Control Solutions, Inc., Des Moines, IA (US)

(21) Appl. No.: 10/780,204

(22) Filed: Feb. 17, 2004

(51) Int. Cl. H03D 3/18; G05B 13/02

(52) U.S. Cl. 700/52; 700/28; 700/29

(57) ABSTRACT

A method for controlling a system includes determining the lag in data from a variable signal. The data is arranged in matrices with one column for each variable signal. The columns are shifted to produce a plurality of different shifted matrices, each shifted matrix having a given value for the lag in data for each variable signal. A variable signal estimator processes each shifted matrix to output a variable signal function defining each variable signal in terms of its mathematical dependencies on all of the variable signals. A criterial function processes each variable signal function to provide an optimal lag value for each variable signal. A point calculation algorithm processes each shifted matrix to produce a point for each column. A lag estimator processes each point and optimal lag value to output a lag function defining each lag in terms of its mathematical dependency on all of the variable signals.

### BACKGROUND OF THE INVENTION

The present invention relates to the field of process control methods, more particularly to a process control method for controlling a process with lag in data from a variable signal.

Lag in data from a variable's signal, or “τ”, can be defined in three ways. First, it is the difference between the time when a turbo-machinery system's variable has changed and the time when a transmitter has sent the true value of that variable. Second, it is the difference between the time when the system's variable has started experiencing a change and the time when the change was over. Third, it can be a combination of the first two cases. In short, τ can be defined as a lag in the variable's signal (hereinafter “lag”).

Various methods of accounting for these lags are known in the art of process control. For example, U.S. Publication No. U.S. 2003/0149493 A1 to Blevins et al. (hereinafter “Blevins”) suggests running a routine to determine if process delay time significantly changes over varying operating conditions, and if so, what process or control variables are correlated to that change. Blevins further suggests that the routine may provide a relationship between these variables and the process delay time. However, Blevins fails to teach or suggest a specific mechanism for determining the relationship between the variables and the process delay time (see paragraph [0073] of Blevins). Additionally, U.S. Pat. No. 5,892,679 to He (hereinafter “He”) discusses determining time delays through the use of diagonal matrices.

However, these prior art process control methods of accounting for lags are often inefficient at maximizing the performance of a particular process and/or inefficient at ensuring adequate process stability.

Therefore, a principal object of this invention is to provide a method of determining optimal τ values for each variable using a shifted matrix technique.

A further object of this invention is to provide a method of determining specific lag function based on all of the variables using a shifted matrix technique.

These and other objects will be apparent to those skilled in the art.

### SUMMARY OF THE INVENTION

A method for controlling a system includes determining the lag in data from a variable signal. The data is arranged in matrices with one column for each variable signal. The columns are shifted to produce a plurality of different shifted matrices, each shifted matrix having a given value for the lag in data for each variable signal. A variable signal estimator processes each shifted matrix to output a variable signal function defining each variable signal in terms of its mathematical dependencies on all of the variable signals. A criterial function processes each variable signal function to provide an optimal lag value for each variable signal. A point calculation algorithm processes each shifted matrix to produce a point for each column. A lag estimator processes each point and optimal lag value to output a lag function defining each lag in terms of its mathematical dependency on all of the variable signals.

### DESCRIPTION OF THE DRAWINGS

FIG. 1 is a schematic diagram of the data mining process control system used for controlling a controlled operation, according to the present invention;

FIG. 2 is a graph showing a time series approximator smoothing a variable signal;

FIG. 3 is a schematic diagram illustrating some of the major functional components of a process dynamic identification module according to the invention;

FIG. 4A is a graph showing the true values of a variable;

FIG. 4B is a graph showing transmitted values corresponding with the true values of FIG. 4A, where there is a simple lag in the transmission of a signal in the measured data;

FIG. 4C is a graph showing the true values of a variable;

FIG. 4D is a graph showing transmitted values corresponding with the true values of FIG. 4C, where there is a simple lag in the shift of value of the variable from value x₁ to value x₂;

FIG. 4E is a graph showing the true values of a variable;

FIG. 4F is a graph showing transmitted values corresponding with the true values of FIG. 4E, where there is both a lag in the shift of value of the variable from value x₁ to value x₂ and a lag in the transmission of a signal in the measured data;

FIG. 5 is a graph showing non-linear regression of a time*variables matrix of filtered data; and

FIG. 6 is a graph showing non-linear regression.

### DETAILED DESCRIPTION OF THE PREFERRED EMBODIMENT

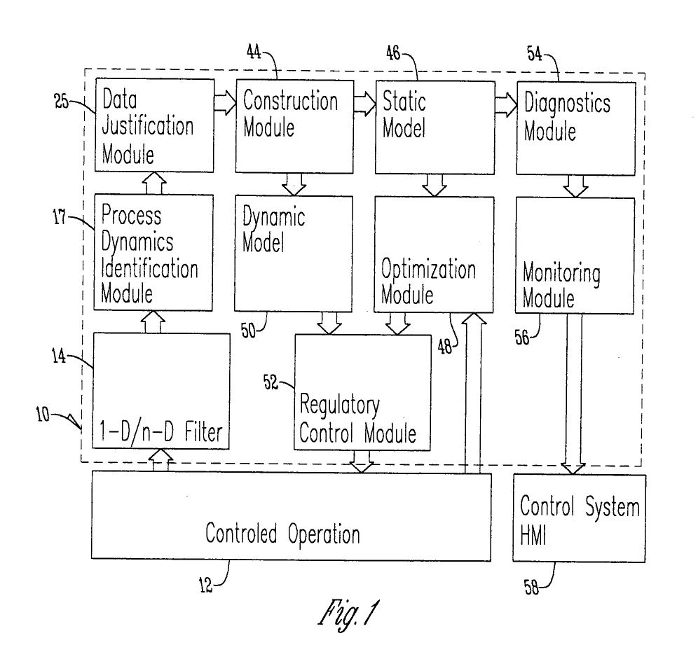

With reference to FIG. 1, the data mining process control system 10 (DMPC) of the present invention provides continuous process control used for controlling the operation of a controlled operation 12, improving the efficiency of that operation and ensuring regulatory compliance. The DMPC 10 includes multiple interrelated modules that interact with a particular controlled operation 12 to build an accurate model for controlling the operation 12. In general, the DMPC 10 analyzes responses of one continuous variable as a function of one or more continuous independent variables to model the operation 12. Thus, while traditional methods of modeling an operation require the operation to be at steady state conditions, the DMPC 10 converts dynamically collected data into correspondent steady state data subsets.

The initial input processing by the DMPC 10 consists of several steps. The filter 14 receives measured process variables data (hereinafter “measured data”) sent from the controlled operation 12. The measured data are the sensed values of the operation 12 variables along with the times that these values arrived into the system.

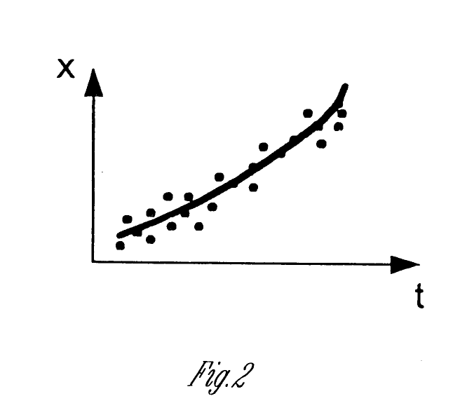

This measured data is first used by the filter algorithm 14. The filter algorithm 14 includes both a 1-D filter and/or an n-D filter. The 1-D filter uses a time series approximator to smooth each variable's signal and reduce noise content, as shown in FIG. 2. Each measured data variable signal is regarded as a variable and the 1-D filter process each variable, rejecting any unusual data observations (i.e. outliers). These smoothed signal values (hereinafter “filtered data”) are used by the DMPC 10 to model the operation 12.

The n-D filter creates a multivariate probability distribution function of the errors in the measured data variable signals to be used by various modules of the DMPC 10. The inputs for the n-D filter algorithm are the residuals from the 1-D filter for “n” predictor variables given by the best subset from the variables.

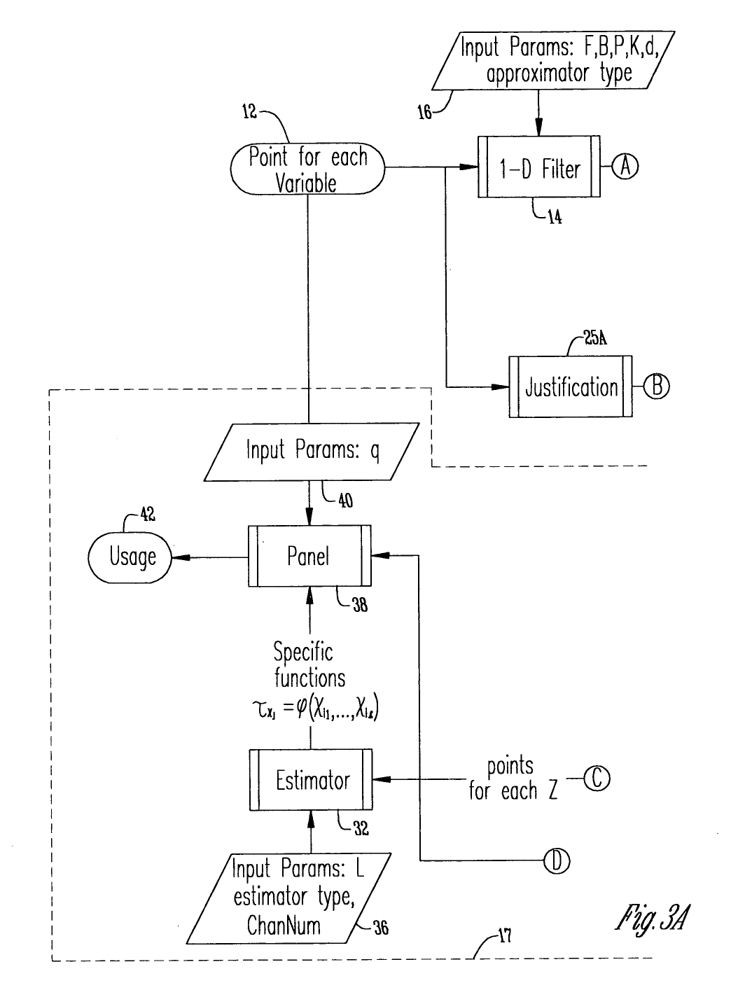

With reference to FIG. 3, in addition to receiving measured data sent from the controlled operation 12, the filter 14 also receives input parameters 16 that assist in producing the filtered data. Specifically, the 1-D filter receives following input parameters 16: F, specifying the width of the filtering window; B, specifying the maximum number of rejected observations; P, specifying the maximum number of iterations for outlier rejection; K, specifying the toleration coefficient for outlier definition; D, specifying the minimum distance between two observations; and an approximator type, specifying the type of approximator chosen and the parameters for that type of approximator.

The result of this 1-D filter algorithm is the ability to predict specific variable values at any given (reasonable) time. This prediction of specific variable values at any given (reasonable) time takes the form of an approximator form for each variable. The approximator form for each variable is a representation of mathematical dependence of each variable on time.

With reference to FIGS. 1 and 3, the output of filter 14 (approximator form) is used by a process dynamic identification module 17. The process dynamic identification module 17 compensates and processes the dynamically collected data to correspondent steady state data subsets.

Specifically, the process dynamic identification module 17 includes a partition algorithm 18 that receives the output of filter 14 (approximator form). For each variable in each filtered data set provided by the filter 14, there exists a parametric range for τ, TauRange (i.e. lag). The following portion of the DMPC 10 process identifies this lag for every variable and also finds the exact mathematical dependence of τ on the variables.

As noted above, lag can be defined in three ways. First, it is the difference between the time when a variable in a controlled operation 12 has changed and the time when a transmitter has sent the true value of that variable. Second, it is the difference between the time when the variable in a controlled operation 12 has started experiencing a change and the time when the change was over. Third, it can be a combination of the first two cases. In short, τ can be defined as a lag in the variable's signal (hereinafter “lag”).

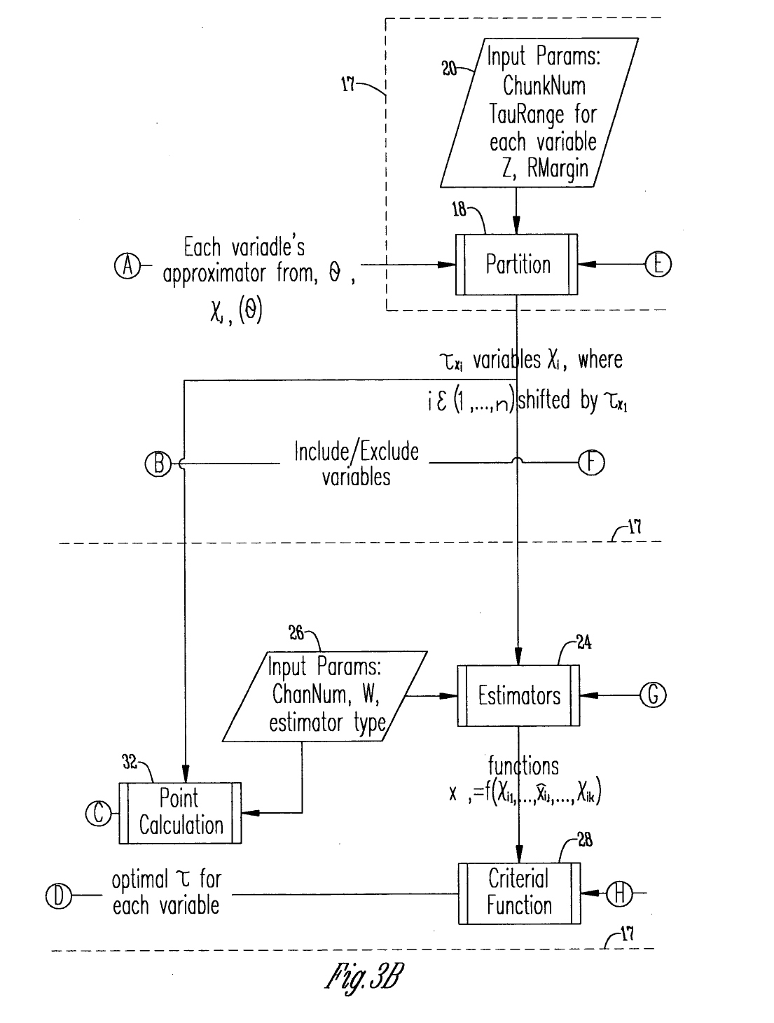

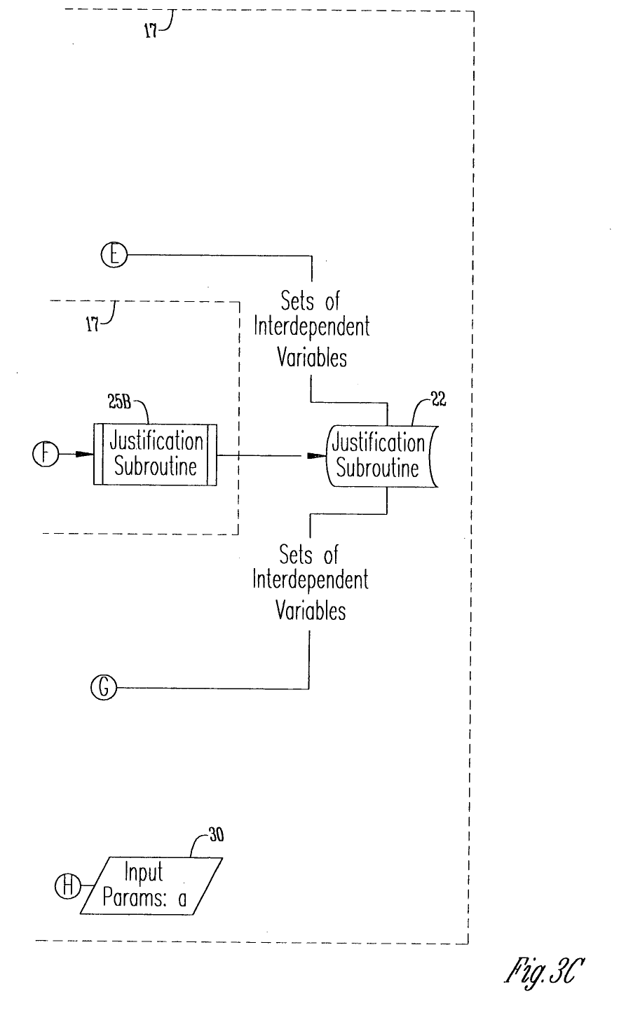

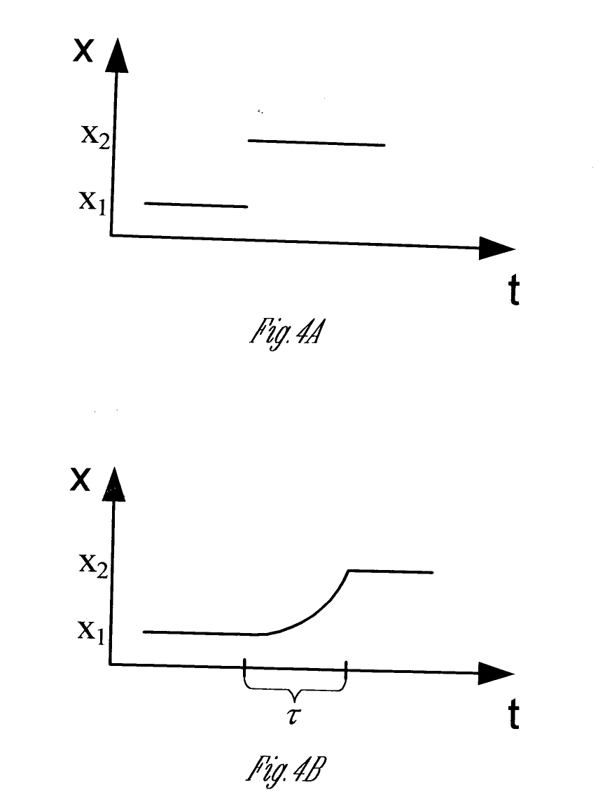

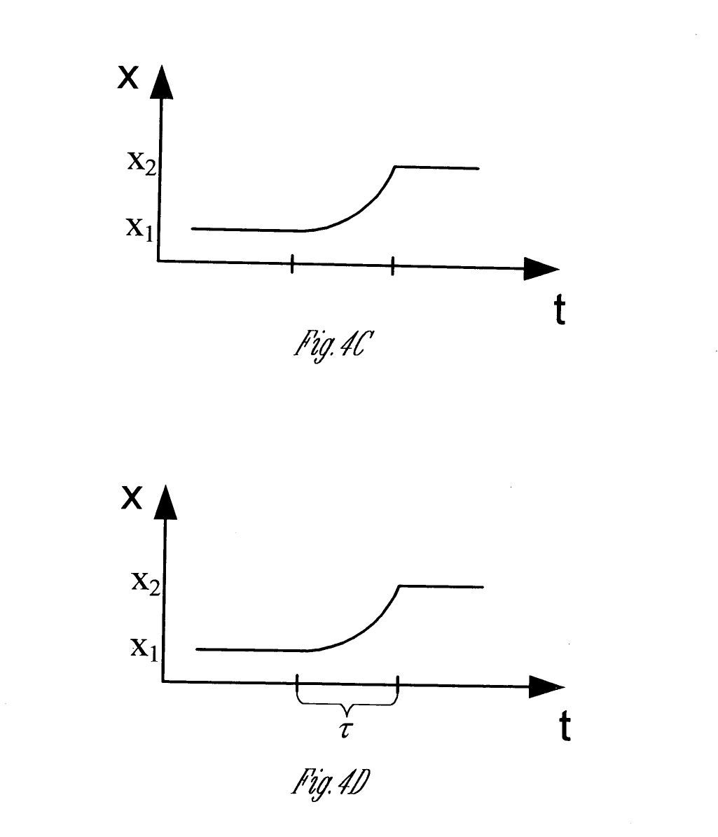

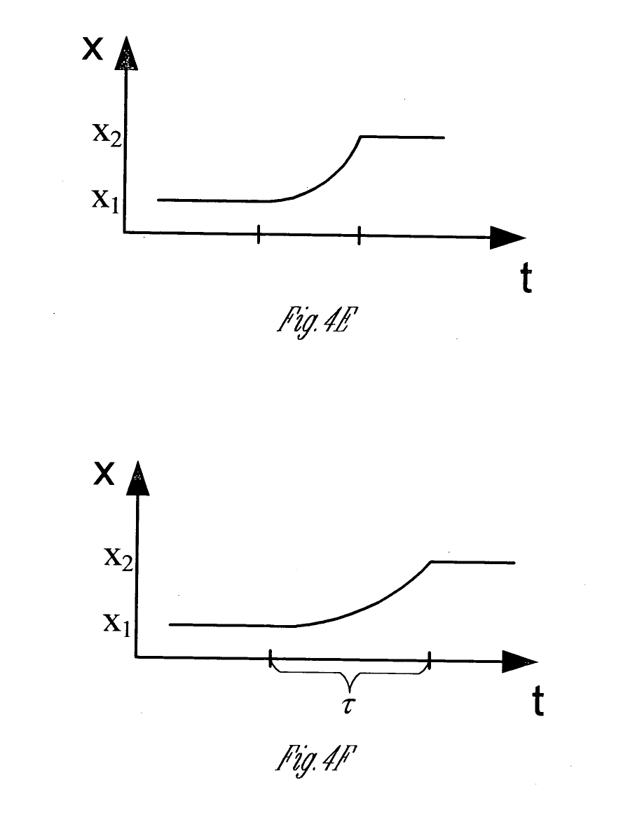

The following gives a graphical illustration of the various definitions of lag, above. With reference to FIGS. 4A-F, FIGS. 4A, 4C, and 4E show true values of the variable, while FIGS. 4B, 4D, and 4F show corresponding transmitted values (i.e. measured data). FIGS. 4A-B show an example of a simple lag in the transmission of a signal in the measured data, but with no lag in the shift of value of the variable from value x₁ to value x₂. FIGS. 4C-D show an example of a pressure change process, where there is a simple lag in the shift of value of the variable from value x₁ to value x₂, but with no lag in the transmission of a signal in the measured data. FIGS. 4E-F show an example of a pressure change process, where there is both a lag in the shift of value of the variable from value x₁ to value x₂ and a lag in the transmission of a signal in the measured data.

With reference to FIG. 3, in addition to receiving an approximator form for each variable (i.e. a representation of mathematical dependence of each variable on time) from the filter 14, a partition algorithm 18 portion of process dynamic identification module 17 also receives input parameters 20 that assist in producing the partitioned data. Specifically, the partition algorithm 18 receives following input parameters 20: TauRange, specifying the range of the values that τ can take on, assigned for each variable; ChunkNum, specifying the number of partitions that each TauRange is split into; Z, specifying the length of columns in the variables*time matrix; and Rmargin, specifying the additional space for variables to move beyond Z.

Additional inputs for this partition algorithm 18 come from a models database 22 of the DMPC 10. The models database 22 is simply a table containing sets of interdependent variables. These are sets of variables that are connected by a certain mathematical function. However, the explicit functions are not required here, only the fact that there exists an association between the variables.

Once the partition algorithm 18 receives the approximator form from the filter 14, input parameters 20, and sets of interdependent variables from the models database 22, the partition algorithm 18 processes all this information arranging the filtered data in matrices with one column for each variable signal and shifts the columns of the matrices to produce a plurality of different shifted matrices. Each of these shifted matrixes have a given value for the lag in data for each variable signal.

As stated above, for each variable in each set provided by the table, there exists a parametric range for τ, TauRange. Each range is split into ChunkNum partitions by the partition algorithm 18. Each partition produces, therefore, certain possible values of τ, as illustrated below: 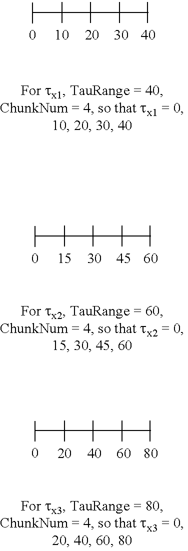
From the illustrations above there are 5*5*5=125 possible combinations of τ.

For a given matrix of filtered data, the matrix if formed with columns of length Z being variables and each row a moment in time. For each combination of τ's the partition algorithm 18 vertically shifts the columns in the matrixes by the values of the corresponding τ's. The room to shift is provided by RMargin from input parameters 20. The result is a collection of the transformed matrices (plurality of different shifted matrices), one for each combination of τ's, which is the Partition algorithm's output. For example, see the illustration below, where the left matrix is the original matrix of time*variables, and the right matrix is a transformed matrix, where the columns have been shifted by a combination of τ's:

$$\begin{matrix} \\ t = {t}_{0} \\ t = {t}_{0} + 1 \\ … \\ t = {t}_{0} + Z\end{matrix} \begin{matrix} {x}_{1} {x}_{2} {x}_{3} \\ ( \begin{matrix}{x}_{1}^{{t}_{0}} & {x}_{2}^{{t}_{0}} & {x}_{3}^{{t}_{0}} \\ {x}_{1}^{{t}_{0} + 1} & {x}_{2}^{{t}_{0} + 1} & {x}_{3}^{{t}_{0} + 1} \\ … & … & … \\ {x}_{1}^{{t}_{0} + Z} & {x}_{2}^{{t}_{0} + Z} & {x}_{3}^{{t}_{0} + Z}\end{matrix} )\end{matrix} {\begin{matrix} {x}_{1} {x}_{2} {x}_{3} \\ {( \begin{matrix}{x}_{1}^{{t}_{0} - 10} & {x}_{2}^{{t}_{0} - 15} & {x}_{3}^{{t}_{0}} \\ {x}_{1}^{{t}_{0} - 9} & {x}_{2}^{{t}_{0} - 14} & {x}_{3}^{{t}_{0} + 1} \\ … & … & … \\ {x}_{1}^{{t}_{0} + Z - 10} & {x}_{2}^{{t}_{0} + Z - 15} & {x}_{3}^{{t}_{0} + Z}\end{matrix} )}_{} \end{matrix}}_{ \begin{matrix}{x}_{1}^{{t}_{0} + Z - 9} & {x}_{2}^{{t}_{0} + Z - 14} & {x}_{3}^{{t}_{0} + Z + 1} \\ {x}_{1}^{{t}_{0} + Z - 8} & {x}_{2}^{{t}_{0} + Z - 13} & {x}_{3}^{{t}_{0} + Z + 2} \\ … & … & …\end{matrix} \} \begin{matrix}\begin{matrix}RMargin \\ \geq \end{matrix} \\ TauRange\end{matrix}}$$

In the transformed matrix above, the columns have been shifted by the following combination of τ's: τₓ_{₁}=10, τₓ_{₂}=8, and τₓ_{₃}=0.

An estimators algorithm 24 processes each shifted matrix from the partition algorithm 18 with a variable signal estimator. The estimators algorithm 24 outputs a variable signal function for each variable signal that defines each variable signal in terms of its mathematical dependencies on all of the variable signals.

Specifically, the estimators algorithm 24 takes as input the sets of interdependent variables in the models database 22, with an additional feature that identifies the variable that depends on others, i.e. the response variable. This response variable is identified in the models database 22, however, it is not needed in the partition algorithm 18. The estimators algorithm 24 then processes each shifted matrix to produce specific mathematical dependencies, i.e. functions connecting together the response variable and the other variables, as illustrated below:

$$\begin{matrix} {x}_{1} {x}_{2} {x}_{3} \\ ( \begin{matrix}{x}_{1}^{{t}_{0}} & {x}_{2}^{{t}_{0}} & {x}_{3}^{{t}_{0}} \\ {x}_{1}^{{t}_{0} + 1} & {x}_{2}^{{t}_{0} + 1} & {x}_{3}^{{t}_{0} + 1} \\ … & … & … \\ {x}_{1}^{{t}_{0} + Z} & {x}_{2}^{{t}_{0} + Z} & {x}_{3}^{{t}_{0} + Z}\end{matrix} )\end{matrix}$$

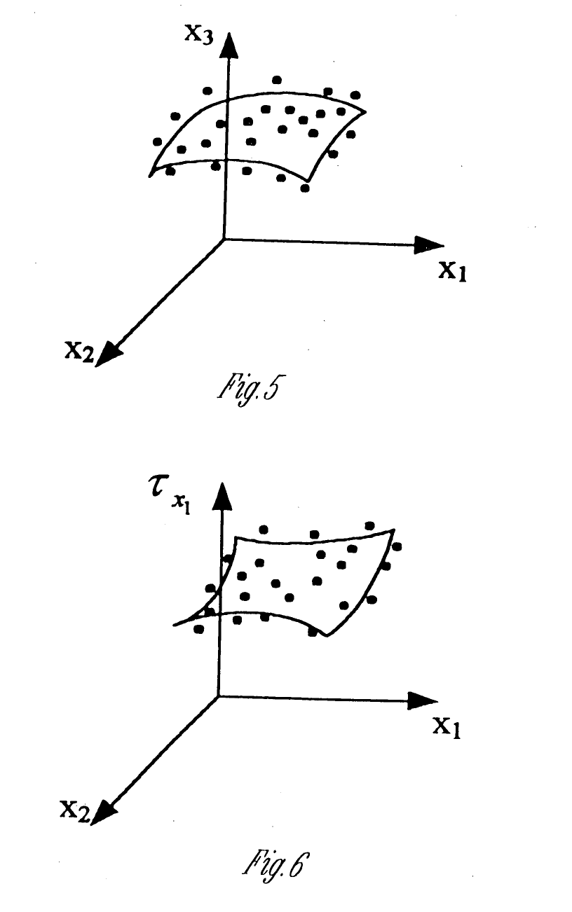

Here the response variable is identified as X₃ and the time*variables matrix of filtered data is processed by the estimators algorithm 24 using non-linear regression, as shown in FIG. 5.

There are many known estimator types suitable for use by the estimators algorithm 24. Specifically, the basic tools (estimator types) that are used to determine the exact mathematical dependencies between variables include: topological-algebraic infinite-dimensional methods, clustering algorithms, self-organized map (SOM) algorithms, expectation-maximization (EM) algorithms, genetic algorithms (GA), maximum likelihood training of hidden Markov model (MLTHMM) algorithms, neural networks, linear and nonlinear correlation and regression algorithms, factor analysis (FA) algorithms, and real-time computation of time-recursive discrete sinusoidal transforms (DST) algorithms.

It should be noted that all the estimator types have their own parameters, coefficients, forms, etc, the correct choice of which will play a major role in accuracy of estimation. For example, a regression algorithm will have minimum and maximum powers for polynomials as parameters. As shown, the estimators algorithm 24 receives input parameters 26 that assist in processing the chosen estimator types. Specifically, the estimators algorithm 24 receives following input parameters 26: ChanNum, specifying the number of variables present in estimation procedure; W, specifying the width of estimating window; and estimator type, specifying the parameters specific to the estimator type chosen.

With reference to FIGS. 1 and 3, two other important algorithms in the DMPC 10 are a justification algorithm 25A and justification subroutine algorithm 25B, contained in the data justification module 25. In general, the data justification module 25 rejects data points when they are beyond a specified distance from expected values generated by a given model. The data justification module 25 also rejects the data points according to certain user-defined criteria.

Specifically, the justification algorithm 25A provides information to the justification subroutine algorithm 25B on whether or not the incoming signals of measured data are valid. As input, the justification algorithm 25A takes unfiltered measured data. If there is something wrong with a given signal of measured data, the justification algorithm 25A invalidates the signal and the justification subroutine algorithm 25B temporarily excludes the entire set of variables connected with the invalidated given signal of measured data from the models database 22 table of interdependent variables. Hence, the models database 22 stops sending all the sets of interdependent variables that contain the invalidated signal to the partition 18 and estimators 24. Once the justification algorithm 25A validates the signal, everything is restored.

With reference to FIG. 3, a criterial function 28 of process dynamic identification module 17 processes each variable signal function from the estimators algorithm 24 to provide an optimal lag value for each variable signal. Specifically, the criterial function algorithm 28 picks up the variable signal functions produced by the estimators algorithm 24 and minimizes (using standard optimization methods, e.g. LSGRG2C available from Optimal Methods, Inc.) the following objective function:

$${\sum }_{i ∈ \{ 1 , … , n \}} {\sum }_{t ∈ W} ( {α}_{i} * \frac{\vert {\overline{x}}_{i} - {f}_{i}^{{τ}_{1} , … , {τ}_{n}} ( {\overline{x}}_{{i}_{1}} , … , {\overline{x}}_{{i}_{k}} ) \vert}{\vert W \vert} ) ,$$

In the function above, where αᵢ's are the parametric weight coefficients, (\overline{x}ᵢ_{₁}, . . . , \overline{x}ᵢ_{ₖ}) is the point calculation algorithm 32 output (discussed in more detail below), and the functions ƒᵢ^{τ}^{₁}^{, . . . , τ}^{ₙ} present the estimators algorithm 24 output. The parametric weight coefficients (αᵢ's) are delivered from input 30 to criterial function 28. The minimization occurs over the combinations of τ mentioned above. Hence, the criterial function algorithm 28 produces an optimal combination of τ's and hence, an optimal value of lag for each variable.

A point calculation algorithm 32 independently processes each shifted matrix from the partition algorithm 18 to produce a point for each column in each transformed matrix (i.e. for each variable) The point calculation algorithm 32 combines every Z value to produce a single point. There are various ways of producing this point, the most common of which is the average value of the column's values.

As shown, the point calculation algorithm 32 receives input parameters 26 that assist in processing the chosen point calculation type. Specifically, the point calculation algorithm 32 receives following input parameters 26: W, specifying the width of point calculation window.

A lag estimator 34 processes each point produced from the point calculation algorithm 32 and each optimal lag value produced from the criterial function algorithm 28 to output a lag function for each lag. Each lag function produced by the lag estimator 30 defining each lag in terms of its mathematical dependency on all of the variable signals.

Specifically, the lag estimator 34 receives points (i.e. values of variables) for each Z (point calculation) and optimal τ's for each variable. The lag estimator 34 finds the mathematical dependence of τ (for every variable) on other variables (including the variable for which we have the given τ). The lag estimator 34 algorithm processes the data similar to the estimators algorithm 24, having an input parameter L, instead of W, and outputs specific functions relating variables' τ's and variables. FIG. 6, shows an example of non-linear regression suitable for the lag estimator 34.

The basic tools (estimator types) used by the lag estimator 34 to determine the exact mathematical dependencies between variables include: topological-algebraic infinite-dimensional methods, clustering algorithms, self-organized map (SOM) algorithms, expectation-maximization (EM) algorithms, genetic algorithms (GA), maximum likelihood training of hidden Markov model (MLTHMM) algorithms, neural networks, linear and nonlinear correlation and regression algorithms, factor analysis (FA) algorithms, and real-time computation of time-recursive discrete sinusoidal transforms (DST) algorithms.

As shown, the lag estimator algorithm 34 receives input parameters 36 that assist in processing the chosen point calculation type. Specifically, the point calculation algorithm 32 receives following input parameters 36: L, specifying the number of windows W; ChanNum, specifying the number of variables present in estimation procedure; and estimator type, specifying the, specific to estimator chosen including parameters.

The final stage of the process dynamic identification module 17 is the panel algorithm 38. In general, the panel algorithm 38 determines the goodness of fit of each lag function from the lag estimator 34 based on the most recent filtered data, stores at least one lag function based on its goodness of fit, and discards other lag functions with inferior goodness of fit.

Specifically, the panel algorithm 38 receives each point produced from the point calculation algorithm 32 and each optimal lag value produced from the criterial function algorithm 28, as well as each lag function from the lag estimator 34. The panel algorithm 38 shelves certain lag functions from the lag estimator 34 according to certain rules.

In a given cycle of data processing, the first lag function is stored on a first shelf of the panel algorithm 38. The next lag function comes in with its own values of the optimal lag value (response variable τ) and filtered data (predictor variables). The panel algorithm 38 plugs the filtered data values into the first lag function and the goodness of fit is evaluated. The panel algorithm 38 at this time knows which of the two lag functions is a better fit to this particular filtered data.

Each following lag function will be compared to all previous lag functions. This process continues indefinitely, however, the panel algorithm 38 should only have q shelves, specified by input parameter 40. Once the q shelves are filled, the shelves with the lag functions of worst goodness of fit values are replaced by the better ones.

The notion of goodness of fit is usually given by the residual standard deviation, but other known methods may be employed. For example, suppose τₓ_{₁}=x₁+2x₁²−7x₁x₃+x₂³ is the first fitted lag function. This first lag function is then placed on the first shelf of the panel algorithm 38. Now, let τₓ_{₁}=5x₁³+2x₁²+x₃ be the second fitted lag function. The second lag function brings with itself the following matrix of filtered data:

$$( \begin{matrix}{τ}_{{x}_{1}}^{{t}_{0}} & {x}_{1}^{{t}_{0}} & {x}_{2}^{{t}_{0}} \\ {τ}_{{x}_{1}}^{{t}_{0} + 1} & {x}_{1}^{{t}_{0} + 1} & {x}_{2}^{{t}_{0} + 1} \\ … & … & … \\ {τ}_{{x}_{1}}^{{t}_{0} + L} & {x}_{1}^{{t}_{0} + L} & {x}_{2}^{{t}_{0} + L}\end{matrix} )$$

The second and third columns of this matrix of filtered data are now plugged into the first fitted lag function and the residual standard deviation is calculated, i.e. the following quotient is computed: the sum of the squared element-wise differences of the first column in the above matrix and the corresponding column of the first fitted function's matrix divided by L. This is a measure of goodness of fit of the second lag function. Now, let q=2, from input parameter 40. Since the second lag function has been considered, the panel algorithm 38 will remember the goodness of fit of the second lag function and place the second lag function on a second shelf. The next lag function, however, will either replace one of the first or second lag functions or will itself be disregarded.

The τ usage output 42 receives a panel of lag functions for every τ for the panel algorithm 38. The τ usage output 42 communicates with other of the multiple interrelated modules of the DMPC 10 for use in building an accurate model for controlling the particular controlled operation 12.

With reference back to FIG. 1, a construction module 44 analyzes responses of one continuous variable as a function of one or more continuous independent variables. The construction module 44 collects measured and/or filtered data and converts it into a static model.

A static model module 46 receives model coefficients generated by the construction module 44. The static model module 46 identifies mathematical dependencies between various process variables. The static model module 46 does not require any apriori physical or thermo dynamical knowledge of the process, and instead operates based on the flow of incoming measured data represented by vectors of real numbers. The static model module 46 uses various statistical and mathematical procedures known in the art (such as clustering algorithms) to group all the process parameters into dependency classes, each with a set of specific mathematical functions. The static model module 46 splits these process parameters into classes and determines functions relating each of the parameters.

An optimization module 48 utilizes the functional dependencies among the variables and the static models produced by the static model module 46, as well as current operating points from the controlled operation 12 to serve several functions. The first, and most important function, is to achieve effective regulatory constraint control. The optimization module 48 uses both the steady-state dependencies and dynamic information to predict how the controlled operation 12 will respond to changes in each of the independent variables. The optimization module 48 is then able to calculate future moves that will maintain the operation at specified targets. Thus, the optimization module 48 can provide real-time set points targets to existing control systems to facilitate operating decisions. Further, the optimization module 48 can also identify controllable losses, track equipment performance against calculated capacity, and identify inefficient processes in order to take corrective action and decrease operating costs.

The dynamic model module 50 collects raw data as well as model coefficients from the construction module 44, and converts these into a dynamic model. The dynamic model module 50 also analyzes responses of a manipulated variable as a function of disturbances of one or more continuous independent variables to form the dynamic model. In general, the dynamic model of the process that can predict future process behavior and the value of the controlled variables based on data collected in the past.

For example, on process plants, the way a process responds to changes may vary with time. Where this response is very severe, it can adversely affect the performance of a control system. The dynamic model module 50 monitors the dynamic behaviors of a given dynamic process and makes adjustments to allow for variations in the process, thereby providing better control.

A regulatory control module 52 is required where a given process: is integrated and multivariable; has significant time delays; is significantly non-linear; and/or operates in different modes, different products, different gas compositions, etc. The most important function of the regulatory control module 52 is to achieve effective regulatory constraint control. The regulatory control module 52 uses both steady-state dependencies and dynamic information to predict how the controlled operation 12 will respond to changes in each of the independent variables.

The regulatory control module 52 uses both the dynamic model produced by the dynamic model module 50 and the static model from the optimization module 48 to calculate the best process adjustment to bring controlled variables to desired set points. These set points can either be generated by the optimization module 48 or be requested by operator. For example, the regulatory control module 52 can employ feed forward control based on both steady-state dependencies and dynamic information that suggest action be taken ahead of time to minimize the effect on the variables being controlled when disturbances are measured.

A diagnostic module 54 is focused on providing meaningful online research for use in minimizing the impact and/or occurrence of critical failures in process equipment. The diagnostic module 54 provides online alarming about abnormal equipment conditions, and monitors degradation of equipment, based at least in part on parameter variations received from the static model module 46. The diagnostic module 54 monitors the degradation of equipment by monitoring benchmark baseline variation of process variables and using them for maintenance decisions. Thus, the diagnostic module 54 allows implementing predictive maintenance scheduling based on equipment state verses planned maintenance.

A monitoring module 56 operates on the same computer with the other components of the DMPC 10 and interacts with them. The monitoring module 56 communicates with a control system HMI 58 to provide an interface between engineering personnel and DMPC 10 system. The monitoring module 56 displays in real-time mode data obtained from the DMPC 10 and can be used to monitor an operating point in relationship to the operating envelope and generated limiting lines based on information obtained from the model. The monitoring module 56 displays historical data as well as predicted scenarios of future operation.

Whereas the invention has been shown and described in connection with the embodiments thereof, it will be understood that many modifications, substitutions, and additions may be made which are within the intended broad scope of the following claims. From the foregoing, it can be seen that the present invention accomplishes at least all of the stated objectives.

1. A method for controlling a controlled operation by determining the lag in measured data from at least one variable signal, comprising:
processing the measured data using time-series analysis with a filter to produce filtered data with reduced noise content;
arranging the filtered data in matrices with one column for each variable signal;
shifting the columns of the matrices to produce a plurality of different shifted matrices, each shifted matrix having a given value for the lag in data for each variable signal;
processing each shifted matrix with a variable signal estimator to output a variable signal function for each variable signal that defines each variable signal in terms of its mathematical dependencies on all of the variable signals;
processing each variable signal function with a criterial function to provide an optimal lag value for each variable signal;
processing each shifted matrix with a point calculation algorithm to produce a point for each column in each shifted matrix;
processing each point and each optimal lag value with a lag estimator to output a lag function for each lag, each lag function defining each lag in terms of its mathematical dependency on all of the variable signals;
determining the goodness of fit of each lag function based on the most recent filtered data;
storing at least one lag function based on its goodness of fit; and
discarding at least one lag function based on its goodness of fit.

2. The method of claim 1, wherein the filter is a 1-D filter.

3. The method of claim 2, wherein the filter is a time series approximator.

4. The method of claim 1, wherein the filter is an n-D filter.

5. The method of claim 1, wherein the variable signal estimator is selected from the group consisting of: topological-algebraic infinite-dimensional methods, clustering algorithms, self-organized map (SOM) algorithms, expectation-maximization (EM) algorithms, genetic algorithms (GA), maximum likelihood training of hidden Markov model (MLTHMM) algorithms, neural networks, linear correlation and regression algorithms, nonlinear correlation and regression algorithms, factor analysis (FA) algorithms, and real-time computation of time-recursive discrete sinusoidal transforms (DST) algorithms.

6. The method of claim 1, wherein the criterial function utilizes optimization methods to provide an optimal lag value for each variable signal.

7. The method of claim 1, wherein the point calculation algorithm averages the values of each column in a given matrix to produce a point for each column in each shifted matrix.

8. The method of claim 1, wherein the lag estimator is selected from the group consisting of: topological-algebraic infinite-dimensional methods, clustering algorithms, self-organized map (SOM) algorithms, expectation-maximization (EM) algorithms, genetic algorithms (GA), maximum likelihood training of hidden Markov model (MLTHMM) algorithms, neural networks, linear correlation and regression algorithms, nonlinear correlation and regression algorithms, factor analysis (FA) algorithms, and real-time computation of time-recursive discrete sinusoidal transforms (DST) algorithms.

9. A method for controlling a controlled operation by determining the lag in measured data from at least one variable signal, comprising:
arranging the data in matrices with one column for each variable signal;
shifting the columns of the matrices to produce a plurality of different shifted matrices, each shifted matrix having a given value for the lag in data for each variable signal;
processing each shifted matrix with a variable signal estimator to output a variable signal function for each variable signal that defines each variable signal in terms of its mathematical dependencies on all of the variable signals; and
processing each variable signal function with a criterial function to provide an optimal lag value for each variable signal.

10. The method of claim 9, wherein the variable signal estimator is selected from the group consisting of: topological-algebraic infinite-dimensional methods, clustering algorithms, self-organized map (SOM) algorithms, expectation-maximization (EM) algorithms, genetic algorithms (GA), maximum likelihood training of hidden Markov model (MLTHMM) algorithms, neural networks, linear correlation and regression algorithms, nonlinear correlation and regression algorithms, factor analysis (FA) algorithms, and real-time computation of time-recursive discrete sinusoidal transforms (DST) algorithms.

11. The method of claim 9, wherein the criterial function utilizes optimization methods to provide an optimal lag value for each variable signal.

12. A method for controlling a controlled operation by determining the lag in measured data from at least one variable signal, comprising:
arranging the data in matrices with one column for each variable signal;
shifting the columns of the matrices to produce a plurality of different shifted matrices, each shifted matrix having a given value for the lag in data for each variable signal;
processing each shifted matrix with a variable signal estimator to output a variable signal function for each variable signal that defines each variable signal in terms of its mathematical dependencies on all of the variable signals;
processing each variable signal function with a criterial function to provide an optimal lag value for each variable signal;
processing each shifted matrix with a point calculation algorithm to produce a point for each column in each shifted matrix; and
processing each point and each optimal lag value with a lag estimator to output a lag function for each lag, each lag function defining each lag in terms of its mathematical dependency on all of the variable signals.

13. The method of claim 12, wherein the variable signal estimator is selected from the group consisting of: topological-algebraic infinite-dimensional methods, clustering algorithms, self-organized map (SOM) algorithms, expectation-maximization (EM) algorithms, genetic algorithms (GA), maximum likelihood training of hidden Markov model (MLTHMM) algorithms, neural networks, linear correlation and regression algorithms, nonlinear correlation and regression algorithms, factor analysis (FA) algorithms, and real-time computation of time-recursive discrete sinusoidal transforms (DST) algorithms.

14. The method of claim 12, wherein the criterial function utilizes optimization methods to provide an optimal lag value for each variable signal.

15. The method of claim 12, wherein the point calculation algorithm averages the values of each column in a given matrix to produce a point for each column in each shifted matrix.

16. The method of claim 12, wherein the lag estimator is selected from the group consisting of: topological-algebraic infinite-dimensional methods, clustering algorithms, self-organized map (SOM) algorithms, expectation-maximization (EM) algorithms, genetic algorithms (GA), maximum likelihood training of hidden Markov model (MLTHMM) algorithms, neural networks, linear correlation and regression algorithms, nonlinear correlation and regression algorithms, factor analysis (FA) algorithms, and real-time computation of time-recursive discrete sinusoidal transforms (DST) algorithms.
